(19) United States
(12) Patent Application Publication
(10) Pub. No.: US 2024/0194483 A1
(43) Pub. Date: Jun. 13, 2024

(54) INTEGRATED CIRCUIT (IC) DEVICE WITH MULTI-PITCH PATTERN FABRICATED THROUGH CROSS-LINKABLE BLOCK COPOLYMER

(71) Applicant: Intel Corporation, Santa Clara, CA (US)

(72) Inventors: Eungnak Han, Portland, OR (US); Florian Gstrein, Portland, OR (US); Gurpreet Singh, Portland, OR (US)

(73) Assignee: Intel Corporation, santa Clara, CA (US)

(21) Appl. No.: 18/064,352

(22) Filed: Dec. 12, 2022

(51) Int. Cl. H01L 21/027; H01L 21/033; H01L 21/8234; H01L 23/528; H01L 23/532; H01L 27/088

(52) U.S. Cl. CPC H01L 21/0274; H01L 21/0332; H01L 21/0337; H01L 21/823475; H01L 23/5283; H01L 23/53295; H01L 27/088

(57) ABSTRACT

A cross-linkable diblock copolymer can facilitate multi-pitch patterning for forming an IC device. The IC device may include a metal layer with different pitches. The metal layer may include a first region having a first pitch and a second region having a second pitch that is greater than the first pitch. The cross-linkable diblock copolymer may be deposited over the metal layer. The portion of the diblock copolymer over the second region may be exposed to light (e.g., UV), which causes cross-linking of functional groups in the diblock copolymer. The cross-linking may form a structure that includes an amorphous phase of the diblock copolymer. The structure may be over and aligned with the second region of the metal layer. After the structure is formed, the diblock copolymer over the first region may self-assemble and form lamellar structures that are aligned with metal lines and insulative structures in the first region.

### BACKGROUND

IC fabrication usually includes two stages. The first stage is referred to as the front end of line (FEOL). The second stage is referred to as the back end of line (BEOL). In the FEOL, individual components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on. Directed self-assembly (DSA) of block copolymers has been used for fabricating metal layers in the BEOL phase.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising an FEOL section and a BEOL section, according to some embodiments of the disclosure.

FIG. 2 illustrates a metal layer with multiple metal pitches, according to some embodiments of the disclosure.

FIGS. 3A-3E illustrate multi-pitch patterning through a cut mask, according to some embodiments of the disclosure.

FIGS. 4A-4E illustrate multi-pitch patterning through a cross-linkable block copolymer, according to some embodiments of the disclosure.

FIGS. 5A-5B are top views of a wafer and dies that may include one or more multi-pitch patterns fabricated through one or more cross-linkable copolymers, according to some embodiments of the disclosure.

FIG. 6 is a side, cross-sectional view of an example IC package that may include one or more IC devices having one or more multi-pitch patterns fabricated through one or more cross-linkable copolymers, according to some embodiments of the disclosure.

FIG. 7 is a cross-sectional side view of an IC device assembly that may include components having one or more IC devices implementing one or more multi-pitch patterns fabricated through one or more cross-linkable copolymers, according to some embodiments of the disclosure.

FIG. 8 is a block diagram of an example computing device that may include one or more components with one or more multi-pitch patterns fabricated through one or more cross-linkable copolymers, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Patterns of metal lines, insulators, or vias in IC devices are often generated through DSA of block copolymers. Phase separation during the DSA of a block copolymer can produce a DSA pattern that includes lamellar structures of polymers. Taking a block copolymer including polymer A and polymer B for example, the DSA of the block copolymer may form lamellar structures including polymer A and lamellar structures including polymer B. The two types of lamellar structures alternate. The center-to-center distance between two adjacent lamellar structures including the same polymer may define a pitch of the DSA pattern.

However, DSA of a block copolymer is limited to a single pitch pattern. The pitch of the DSA pattern is fixed, e.g., based upon the molecular weight of the block copolymer. Examples of pitches of DSA patterns may include, for example, 33 nanometers (nm), 34 nm, 36 nm, 38 nm, 39 nm, and so on. However, the fabrication of an IC device may require formation of a DSA pattern over a layer (e.g., a metal layer) that has a multi-pitch pattern, meaning the layer has at least two different pitches. For instance, the layer may have a first region with one pitch and a second region with a different pitch. The pitch of DSA pattern cannot match both pitches. Conventional fabrication technologies usually ensure that the pitch of DSA pattern matches one of the pitches of the underlying layer and therefore, is different from other pitches of the underlying layer. Given the multi-pitch pattern in the underlying layer, the DSA pattern may be inevitably formed over an undesired area, such as the region that has a different pitch from the pitch of the DSA pattern. These conventional fabrication technologies typically require additional lithography steps to remove the DSA pattern formed over the undesired area, e.g., by using a cut mask. These conventional fabrication technologies also require additional lithography steps to generate the multi-pitch pattern that cannot be generated through DSA. Given the fallbacks of the conventional fabrication technologies, improved technologies for multi-pitch patterning are needed.

Embodiments of the present disclosure may improve on at least some of the challenges and issues described above by using cross-linkable block copolymers for multi-pitch patterning. In various embodiments of the present disclosure, a cross-linkable diblock copolymer may be provided to a surface of a layer having a multi-pitch pattern. The layer may include a first region including a first group of metal lines with a first pitch and a second region including a second group of metal lines with a second pitch. The second pitch may be greater than the first pitch. A pitch may be the center-to-center distance between two adjacent metal lines. A molecule of the cross-linkable block copolymer may include a block of polymer A and a block of polymer B. Polymer A or polymer B (or both) may include one or more functional groups. Examples of the functional groups include epoxide group, azide group, vinyl group, cinnamoyl group, propargyl group, and so on. The functional groups can facilitate cross-linking of chains of the block copolymer through light radiation. For instance, the chains of the block copolymer can be cross-linked by exposing the block copolymer to light, such as UV (ultraviolet) light. The cross-linking may result in an amorphous phase of the block copolymer, which prevents self-assembly of the block copolymer.

The light exposure can be controlled so that the block copolymer over the second region of the layer is exposed to the light and the block copolymer over the first region of the layer is not exposed to the light. That way, the block copolymer over the first region can self-assemble to form a DSA pattern, but the block copolymer over the second region cannot self-assemble and will remain as the amorphous phase. By controlling the light exposure, the amorphous block copolymer can be aligned with the second region of the layer to avoid formation of the DSA pattern over the second region. This can avoid the formation of the DSA pattern over an undesired area (e.g., the second region) and therefore, the necessity of using a cut mask to remove such DSA pattern is negated. Further, the present disclosure can also avoid formation of hard masks over the undesired area and therefore avoid the removal of the undesired hard masks.

Compared with the conventional fabrication technologies, the present disclosure does not require additional cut mask or lithography step to print features that are not compatible with the single pitch DSA pattern. Thus, the present disclosure provides a more advantageous multi-pitch patterning method.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

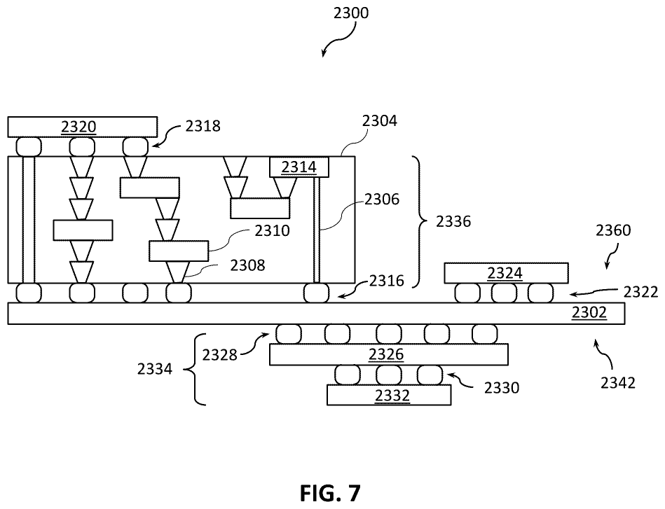

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of one or more multi-pitch patterns fabricated through one or more cross-linkable copolymers as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various one or more multi-pitch patterns fabricated through one or more cross-linkable copolymers as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

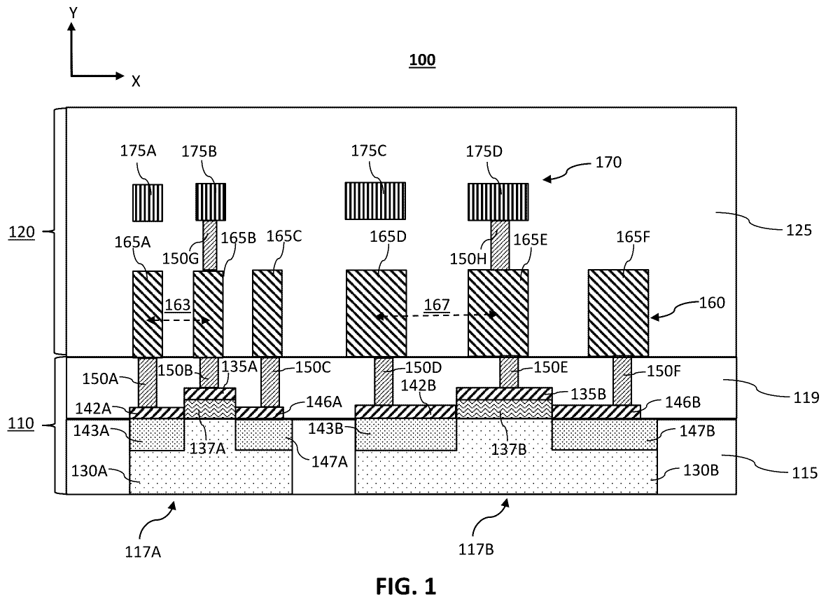

FIG. 1 illustrates an IC device 100 comprising an FEOL section 110 and a BEOL section 120, according to some embodiments of the disclosure. The FEOL section 110 includes a support structure 115, two transistors 117A and 117B (collectively referred to as “transistors 117” or “transistor 117”), vias 150A-150F, and an insulative structure 119. The BEOL section 120 includes metal layers 160 and 170, vias 150G and 150H, and an insulative structure 125. In other embodiments, the IC device 100 may include fewer, more, or different components. For instance, the FEOL section 110 may include a different number of transistors or other semiconductor devices not shown in FIG. 1. Also, the BEOL section 120 may include fewer or more metal layers.

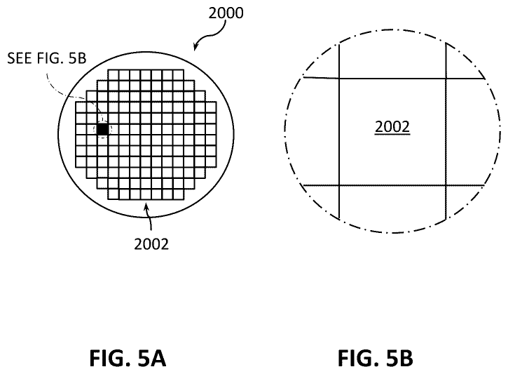

The support structure 115 may be any suitable structure, such as a substrate, a die, a wafer, or a chip, based on which the transistors 117 can be built. The support structure 115 may, e.g., be the wafer 2000 of FIG. 5A, discussed below, and may be, or be included in, a die, e.g., the singulated die 2002 of FIG. 5B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

A transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 117A includes a semiconductor structure that includes a channel region 130A, a source region 143A, and a drain region 147A. The transistor 117A includes a semiconductor structure that includes a channel region 130B, a source region 143B, and a drain region 147B. The channel regions 130A and 130B are collectively referred to as “channel regions 130” or “channel region 130.” The source regions 143A and 143B are collectively referred to as “source regions 143” or “source region 143.” The drain regions 147A and 147B are collectively referred to as “drain regions 147” or “drain region 147.”

The semiconductor structure of each transistor 117 may be at least partially in the support structure 115. The support structure 115 may include a semiconductor material, from which at least a portion of the semiconductor structure is formed. The semiconductor structure of a transistor 117 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

Each channel region 130 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example n-type transistor embodiments (i.e., for the embodiments where the transistor 117 is an NMOS (N-type metal-oxide-semiconductor) transistor or an n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a Ill-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the transistor 117 is a PMOS (P-type metal-oxide-semiconductor) transistor or a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In each transistor 117, the source region 143 and the drain region 147 are connected to the channel region 130. The source region 143 and the drain region 147 each includes a semiconductor material with dopants. In some embodiments, the source region 143 and the drain region 147 have the same semiconductor material, which may be the same as the channel material of the channel region 130. A semiconductor material of the source region 143 or the drain region 147 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 143 and the drain region 147 are the same type. In other embodiments, the dopants of the source region 143 and the drain region 147 may be different (e.g., opposite) types. In an example, the source region 143 has n-type dopants and the drain region 147 has p-type dopants. In another example, the source region 143 has p-type dopants and the drain region 147 has n-type dopants. Example n-type dopants include Te, S, As, tin (Sn), Si, Ga, Se, S, In, Al, Cd, chlorine (CI), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the source region 143 and the drain region 147 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 143 and the drain region 147 may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 143 and the drain region 147. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 143 and the drain region 147, for example below 10¹⁵ cm⁻³ or below 10¹³ cm⁻³. Depending on the context, the term “S/D terminal” may refer to a S/D region or a S/D contact or electrode of a transistor.

The transistor 117A also includes a source contact 142A over the source region 143A and a drain contact 146A over the drain region 147A. The transistor 117B also includes a source contact 142B over the source region 143B and a drain contact 146B over the drain region 147B. The source contacts 142A and 142B are collectively referred to as “source contacts 142” or “source contact 142.” The drain contacts 146A and 146B are collectively referred to as “drain contacts 146” or “drain contact 146.” The source contacts 142 and the drain contacts 146 are electrically conductive and may be coupled to source and drain terminals for receiving electrical signals. A source contact 142 or the drain contact 146 includes one or more electrically conductive materials, such as metals. Examples of metals in the source contacts 142 and the drain contacts 146 may include, but are not limited to, Ruthenium (Ru), copper (Cu), cobalt (Co), palladium (Pd), platinum (Pt), nickel (Ni), and so on.

Each transistor 117 also includes a gate that is over or wraps around at least a portion of the channel region 130. The gate of the transistor 117A includes a gate electrode 135A and a gate insulator 137A. The gate of the transistor 117B includes a gate electrode 135B and a gate insulator 137B. The gate electrodes 135A and 135B are collectively referred to as “gate electrodes 135” or “gate electrode 135.” The gate insulators 137A and 137B are collectively referred to as “gate insulators 137” or “gate insulator 137.” In each transistor 117, the gate electrode 135 can be coupled to a gate terminal that controls gate voltages applied on the transistor 117. The gate electrode 135 may include one or more gate electrode materials, where the choice of the gate electrode materials may depend on whether the transistor 117 is a p-type transistor or an n-type transistor. For a p-type transistor, gate electrode materials that may be used in different portions of the gate electrode may include, but are not limited to, Ru, Pd, Pt, Co, Ni, and conductive metal oxides (e.g., ruthenium oxide). For an n-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate insulator 137 separates at least a portion of the channel region 130 from the gate electrode 135 so that the channel region 130 is insulated from the gate electrode 135. In some embodiments, the gate insulator 137 may wrap around at least a portion of the channel region 130. The gate insulator 137 may also wrap around at least a portion of the source region 143 or the drain region 147. At least a portion of the gate insulator 137 may be wrapped around by the gate electrode. The gate insulator 137 includes an electrical insulator, such as a dielectric material, hysteretic material, and so on. Example dielectric material includes oxide (e.g., Si based oxides, metal oxides, etc), high-k dielectric, and so on. Example hysteretic material include ferroelectric materials, antiferroelectric materials, etc.

In the embodiments of FIG. 1, the transistors 117 are coupled to the metal layer 160 through the vias 150A-150F. The metal layer 160 is further coupled to the metal layer 170 through the vias 150G and 150H. The vias 150A-150H are collectively referred to as “vias 150” or “via 150”. A via 150 may be electrically conductive. A via 150 may include a metal, such as Co, Cu, aluminum (AI), Al-doped Cu, Ru, Molybdenum (Mo), Titanium (Ti), Tungsten (W), and so on. Different vias 150 may include different materials. The vias 150 can provide conductive channels among the transistors 117 and the metal layers 160 and 170.

The metal layers 160 and 170 are stacked over the transistors 117 along the Y axis. A metal layer 160 or 170 may also be referred to as an interconnect set. A metal layer 160 or 170 may include one or more metal lines. A metal line may also be referred to as an interconnect. The metal layer 160 may be the metal layer that is arranged closest to the FEOL section 110. In some embodiments, the metal layer 160 may be referred to as M0. The metal layer 170 may be referred to as M1. There may be one or more metal layers that are arranged on top of the metal layer 170, which may be referred to as M2, M3, M4, and so on. Certain portions of the metal layers 160 and 170 may be insulated from each other by an insulative structure 125. The insulative structure 125 may include one or more electrical insulators. An electrical insulator may be a dielectric material, hysteretic material, and so on. The dielectric material may be low-k dielectric, high-k dielectric, and so on. Examples of the dielectric material include silicon oxides, doped silicon oxides, fluorinated silicon oxides, carbon doped oxides, metal oxide (e.g., alumina, etc.), carbon nitride, carbide, and so on. The hysteretic material may be ferroelectric materials, antiferroelectric materials, and so on.

The metal layer 160 includes metal lines 165A-165F (collectively referred to as “metal lines 165” or “metal line 165”). The metal lines 166 are in parallel with each other. Each metal line 165 may have a longitudinal axis along the Y axis. For purpose of illustration, FIG. 1 shows six metal lines in the metal layer 160. In other embodiments, the metal layer 160 may include fewer or more metal lines. Each metal line 165 is an electrically conductive structure. In some embodiments, an individual one of the metal lines 165A-165D includes a metal, such as Co, Al, Cu, Al-doped Cu, Ru, Mo, Ti, W, and so on. The metal lines 165 are shown as rectangles in FIG. 1. The metal lines 165 may have different shapes.

The metal layer 160 is connected to the transistors 117 through the vias 150A-150F. The vias 150A-150F are separated from each other by one or more electrical insulators in the insulative structure 119. An electrical insulator may be a dielectric material, hysteretic material, and so on. The dielectric material may be low-k dielectric, high-k dielectric, and so on. Examples of the dielectric material include silicon oxides, doped silicon oxides, fluorinated silicon oxides, carbon doped oxides, metal oxide (e.g., alumina, etc.), carbon nitride, carbide, and so on. The hysteretic material may be ferroelectric materials, antiferroelectric materials, and so on.

For purpose of illustration, the metal line 165A is connected to the source contact 142A through the via 150A, the metal line 165B is connected to the gate electrode 135A through the via 150B, the metal line 165C is connected to the drain contact 146A through the via 150C, the metal line 165D is connected to the source contact 142B through the via 150D, the metal line 165E is connected to the gate electrode 135B through the via 150E, and the metal line 165F is connected to the drain contact 146B through the via 150F. In other embodiments, the electrical connection between the metal layer 160 and the transistors 117 may be different. The metal layer 160 may facilitate controlling operation of the transistors 117 by providing electrical signals to the source contacts 142, the drain contacts 146, and the gate electrodes 135. The metal lines 165A-165F are insulated from each other by one or more electrical insulators in the insulative structure 125. Some or all of the metal lines 165A-165F may be at different electrical potentials during operation of the IC device 100.

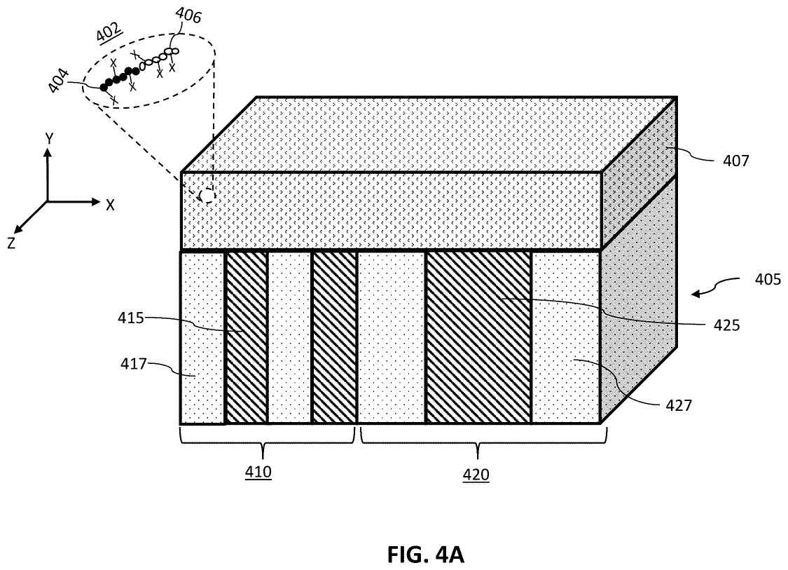

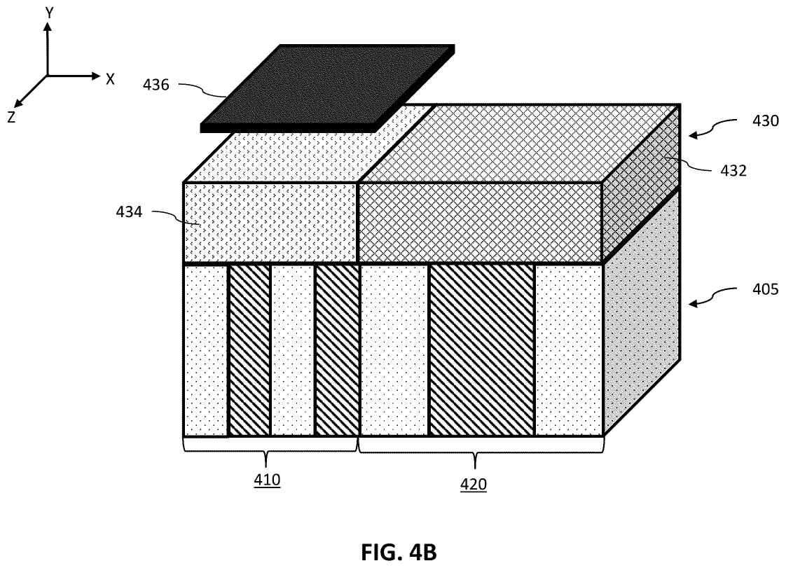

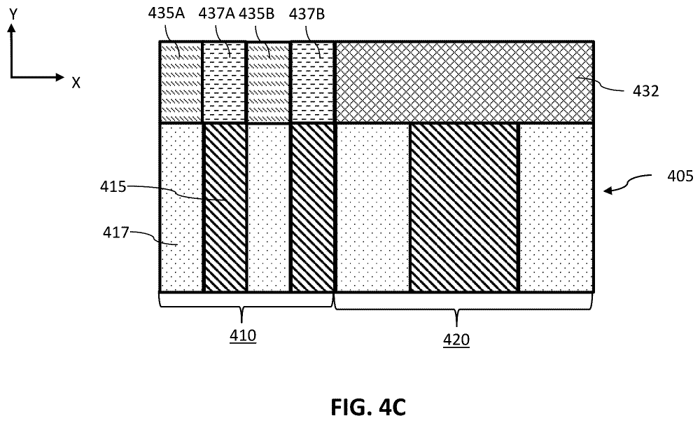

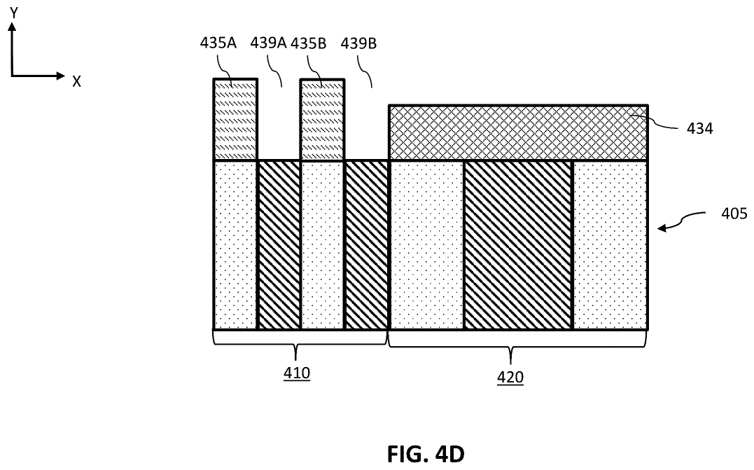

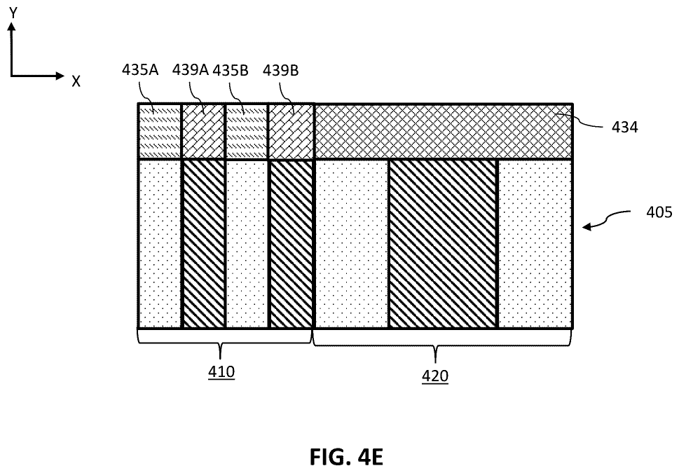

In the embodiments of FIG. 1, the metal layer 160 has a multi-pitch pattern. The metal lines 165A-165C has a pitch 163. The metal lines 165D-165F has a pitch 167. The pitch 167 is greater than the pitch 163. The fabrications of structures over the metal layer 160 may be based on the multi-pitch pattern of the metal layer 160. Examples of the structures over the metal layer 160 include the vias 150 and the metal lines 175. In some embodiments, the vias 150 or the metal lines 175 are fabricated after the metal layer 160 is formed. The process of forming the vias 150 or the metal lines 175 may include a multi-pitch patterning process facilitated by a copolymer, such as a cross-linkable diblock copolymer. More details regarding the multi-pitch patterning process are provided below in conjunction with FIGS. 4A-4E.

The metal layer 170 includes metal lines 175A-175D (collectively referred to as “metal lines 175” or “metal line 175”). The metal lines 175 are electrically conductive. The metal lines 175 may include one or more metals. A metal in the metal lines 175 may be the same as the metal in one of the metal lines 165. In some embodiments, longitudinal axes of the metal lines 175 are in parallel, but the longitudinal axes of the metal lines 175 are not in parallel with longitudinal axes of the metal lines 165. In an embodiment, the longitudinal axes of the metal lines 175 may be orthogonal (or substantially orthogonal) to the longitudinal axes of the metal lines 165. For instance, the longitudinal axes of the metal lines 175 may be perpendicular to the X-Y plane.

The metal line 175B is coupled to the metal line 165B through the via 150G. The metal line 175D is coupled to the metal line 165E through the via 150H. The other metal lines 175 are not coupled to the metal layer 160 in the embodiments of FIG. 1. In other embodiments, electrical coupling between the metal layers 160 and 170 may be different from the electrical coupling shown in FIG. 1. The metal layers 160 and 170 may facilitate supply of electrical signals to the transistors 117. Even though not shown in FIG. 1, the metal layer 160 or 170 may be coupled with other devices than the transistors 117, such as diodes, power sources, resistors, capacitors, inductors, sensors, transceivers, receivers, antennas, and so on. The metal layer 160 or 170 may include a different number of metal lines than the number of metal lines shown in FIG. 1.

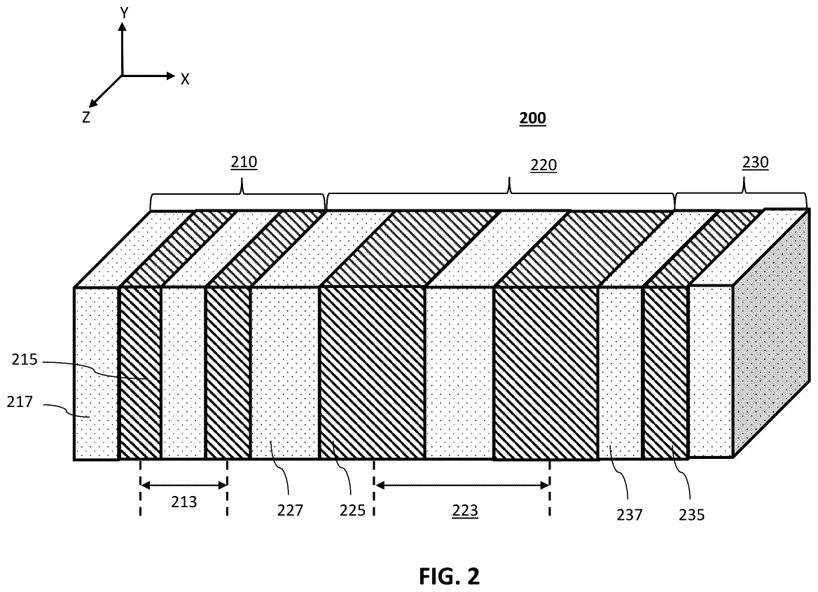

FIG. 2 illustrates a metal layer 200 with multiple metal pitches, according to some embodiments of the disclosure. The metal layer 200 may be an embodiment of the metal layer 160 or 170 in FIG. 1. As shown in FIG. 2, the metal layer 200 includes an active region 210, a transition region 220, and another active region 230. In other embodiments, the metal layer 200 may include fewer, more or different regions.

The active region 210 include conductive structures 215 (individually referred to as “conductive structure 215”) and insulative structures 217 (individually referred to as “insulative structure 217”). The conductive structures 215 have longitudinal axes along the Y axis. Two adjacent conductive structures 215 are separated by an insulative structure 217. A pitch 223 of the conductive structures 215 is a center-to-center distance between two adjacent conductive structures 215 along the X axis.

The transition region 220 include conductive structures 225 (individually referred to as “conductive structure 225”) and insulative structures 227 (individually referred to as “insulative structure 227”). The conductive structures 225 have longitudinal axes along the Y axis. Two adjacent conductive structures 225 are separated by an insulative structure 227. A pitch 223 of the conductive structures 225 is a center-to-center distance between two adjacent conductive structures 225 along the X axis. The pitch 223 is greater than the pitch 221 of the active region 210.

The active region 230 include a conductive structure 235 and insulative structures 237 (individually referred to as “insulative structure 237”). The conductive structure 235 has a longitudinal axis along the Y axis. The conductive structure 235 is separated by a conductive structure 225 in the transition region 220 by an insulative structure 227. For purpose of illustration, FIG. 2 shows one conductive structure 235 in the active region 230. In other embodiments, the active region 230 may include more conductive structures 235. A pitch of the conductive structure 235 in the active region 230 may be the same or similar as the pitch 223 of the active region 210.

In some embodiments, the metal layer 200 may be M0, M1, M2, and so on. For instance, the metal layer 200 may be an embodiment of the metal layer 160 in FIG. 1. A conductive structure 215 or 235 may be an example of at least one of the metal lines 165A-165C in FIG. 1. A conductive structure 225 may be an example of at least one of the metal lines 165D-165F in FIG. 1. In other embodiments, a conductive structure 215, 225, or 235 may be a contact of a transistor, such as a gate contact, source contact, or drain contact of a transistor.

Due to the differences in the pitches 213 and 223, the metal layer 200 has a multi-pitch pitch pattern, which causes challenges to pattern over the metal layer 200 through DSA of block copolymers, as DSA of block copolymer is usually limited to single pitch pattern. The single pitch pattern may be defined by an average molecular weight of the block copolymer. In an example, the average molecular weight block copolymer may be compatible with the pitch pattern of the active region 210 or 230 so that the conductive structure-insulative structure alternating pattern in the active region 210 or 230 may function as a guiding pattern for the DSA of the block copolymer. Lamellar structures formed through the self-assembly of the block copolymer can align with the conductive structure and insulative structures in the active regions 210 and 230.

However, given that the transition region 220 has a different pitch pattern, the average molecular weight block copolymer is incompatible with the pitch pattern of the transition region 220. Lamellar structures would fail to align with the conductive structure 225 or insulative structures 227 in the transition region 220. This can result in undesired DSA single pitch, random fingerprint pattern, horizontal morphology, or some combination thereof over the transition region 220. These undesired patterns formed over the transition region 220 need to be removed, e.g., through cut mask. Additional lithography steps are therefore needed, which can reduce time and cost efficiency of IC fabrication.

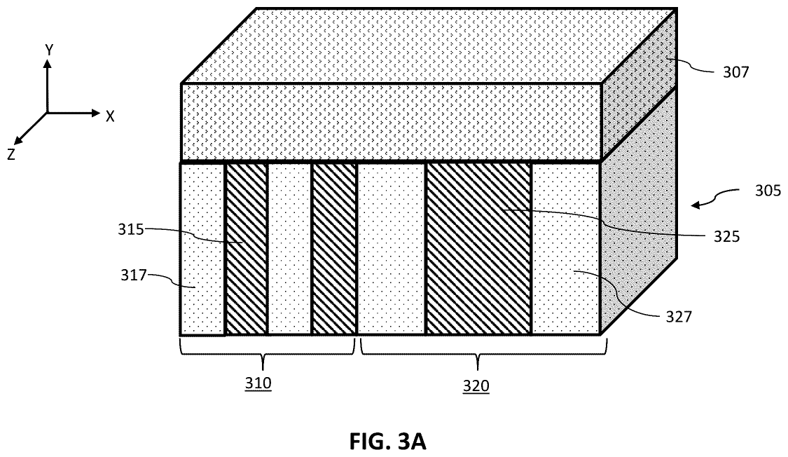

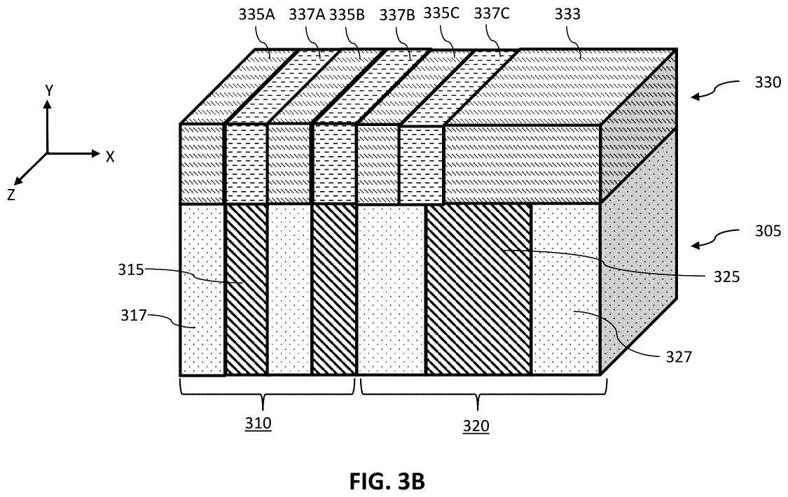

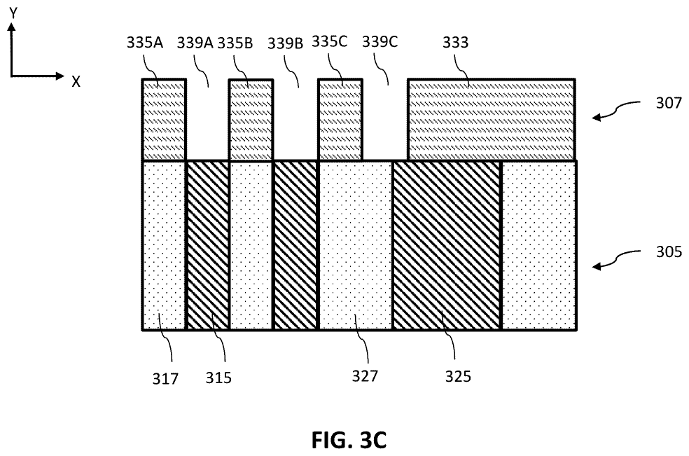

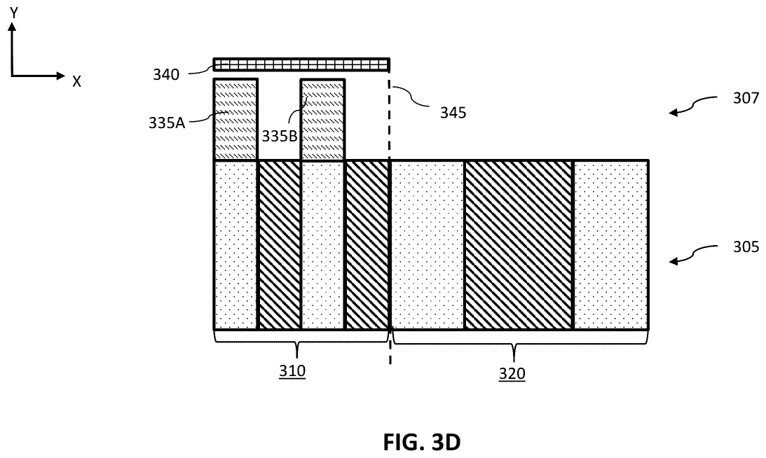

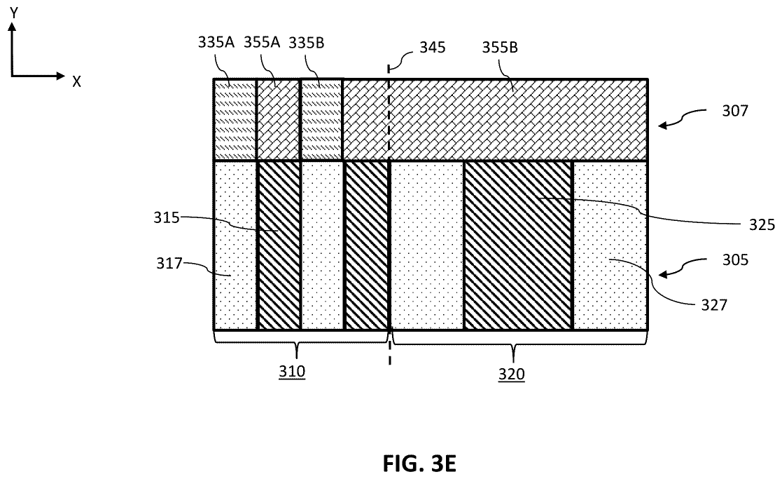

FIGS. 3A-3D illustrate multi-pitch patterning through a cut mask 340, according to some embodiments of the disclosure. FIG. 3A shows a layer 305. The layer 305 may be an embodiment of a portion of the metal layer 200 in FIG. 2. The layer 305 includes a region 310 and a region 320. The region 310 may be an embodiment of the active region 210 or 230 in FIG. 2. The region 320 may be an embodiment of the transition region 220 in FIG. 2. In other embodiments, the layer 305 may include more or different regions. For instance, the layer 305 may include another active region arranged at the opposite side of the region 320 from the region 310.

As shown in FIG. 3A, the region 310 include conductive structures 315 (individually referred to as “conductive structure 315”) and insulative structures 317 (individually referred to as “insulative structure 317”). The conductive structures 315 alternative with the insulative structures 317. The conductive structures 315 have longitudinal axes along the Y axis. Two adjacent conductive structures 315 are separated and insulated by an insulative structure 317. The conductive structures 315 may include one or more metals, such as Co, Al, Cu, Al-doped Cu, Ru, Mo, Ti, W, and so on. The insulative structures 317 may include one or more electrical insulators. An electrical insulator may be a dielectric material, hysteretic material, and so on. The dielectric material may be low-k dielectric, high-k dielectric, and so on. Examples of the dielectric material include silicon oxides, doped silicon oxides, fluorinated silicon oxides, carbon doped oxides, metal oxide (e.g., alumina, etc.), carbon nitride, carbide, and so on. The hysteretic material may be ferroelectric materials, antiferroelectric materials, and so on.

The region 320 include a conductive structure 325 and insulative structures 327 (individually referred to as “insulative structure 327”). The conductive structure 325 is separated from a conductive structure 315 (i.e., the conductive structure 315 that is closest to the conductive structure 325) by an insulative structure 327 (i.e., the insulative structure 327 between the conductive structure 315 and the conductive structure 325). Even though FIG. 3A shows one conductive structure 325 in the transition region, the region 320 may include multiple conductive structures 325, which may be separated by insulative structures 327 that alternate with the conductive structures 325. The region 320 has a larger pitch than the region 310.

A layer 307 is formed over the layer 305. The layer 307 includes a diblock copolymer. The diblock copolymer may include two polymers: polymer A and polymer B. A molecule of the diblock copolymer may include a block of polymer A and a block of polymer B. A chain of the diblock copolymer has a repetitive pattern of blocks of polymer A alternating with blocks of polymer B. An individual block of polymer A includes predominantly a chain of covalently linked monomer A (e.g., A-A-A-A-A . . . ), whereas the block of polymer B includes predominantly a chain of covalently linked monomer B (e.g., B-B-B-B-B . . . ). The monomers A and B may represent any of the different types of monomers used in block copolymers known in the arts. Examples of the polymer A and polymer B include polyethylene, polystyrene, poly(methyl methacrylate), polyvinylchloride, polytetrafluorethylene, polydimethylsiloxane, some polyesters, some polyurethanes, acrylics, epoxies, P(t-Butyl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. In other embodiments, the polymer A or polymer B may be other polymers.

In some embodiments, the block of polymer A and the block of polymer B have different chemical properties. As one example, one of the blocks may be relatively more hydrophobic (e.g., water disliking) and the other may be relatively more hydrophilic (water liking). As another example, one of the blocks may be relatively more similar to oil and the other block may be relatively more similar to water. Such differences in chemical properties between the different blocks of polymers, whether a hydrophilic-hydrophobic difference or otherwise, may cause the diblock copolymer molecule to self-assemble. For example, the self-assembly may be based on microphase separation of the polymer blocks. Conceptually, this may be similar to the phase separation of oil and water which are generally immiscible. Similarly, differences in hydrophilicity between the polymer blocks (e.g., one block is relatively hydrophobic and the other block is relatively hydrophilic), may cause a roughly analogous microphase separation where the different polymer blocks try to separate from each other due to chemical dislike for the other.

However, because the polymer blocks are covalently bonded to one another, they cannot be completely separated on a macroscopic scale. Rather, polymer blocks of a given type may tend to segregate or conglomerate with polymer blocks of the same type of other molecules. Self-assembly of the diblock copolymer, whether based on hydrophobic-hydrophilic differences or otherwise, may be used to form extremely small periodic structures (e.g., precisely spaced nanoscale structures). In some embodiments, the diblock copolymer can be used to form lamellar structures based on which patterning of metal lines, vias, or other components of IC devices may be performed. The dimensions of the lamellar structures are dependent upon the molecular weight, the lengths of the polymer blocks, and so on.

In FIG. 3B, a DSA layer 330 is formed over the layer 305 through DSA of the diblock copolymer in the layer 307. The DSA layer 330 includes lamellar structures 335A-335C (collectively referred to as “lamellar structures 335” or “lamellar structure 335”), lamellar structures 337A-337C (collectively referred to as “lamellar structures 337” or “lamellar structure 337”), and a lamellar structure 333. In some embodiments, the lamellar structures 335 and the lamellar structure 333 includes one of the polymers in the diblock copolymer, and the lamellar structures 337 includes the other polymer in the diblock copolymer. Individual lamellar structures 335 alternative with individual lamellar structures 337, which constitutes a single pitch DSA pattern. The pitch of the DSA pattern is a center-to-center distance between two adjacent lamellar structures 335 or two adjacent lamellar structures 337.

The pitch of the DSA pattern may be the same or similar as the metal pitch of the region 310 but is different from the metal pitch of the region 320. Given the difference from the metal pitch of the region 320, the DSA pattern cannot be formed over the whole region 320. As shown in FIG. 3B, the single pitch DSA pattern is formed over a portion of the region 320 (i.e., the portion over which the lamellar structures 335C and 337C are formed). The rest of the region 320 does not have the DSA pattern. Rather, the lamellar structure 333 is formed over the rest of the region 320.

The formation of the lamellar structures 335 and 337 may be facilitated by the alternating pattern of the conductive structures 315 and insulative structures 317. In some embodiments, the alternating pattern of the conductive structures 315 and insulative structures 317 may constitute a guiding pattern for the DSA of the diblock copolymer. For instance, polymer A in the diblock copolymer may have stronger chemical affinity with the material in the conductive structures 315 than the material in the insulative structures 317. Additionally or alternatively, polymer B in the diblock copolymer may have stronger chemical affinity with the material in the conductive structures 315 than the material in the insulative structures 317. As a result, the lamellar structures 335, which includes polymer A, are formed over the insulative structures 317, and the lamellar structures 335, which includes polymer B, are formed over the conductive structures 315.

In other embodiments, a guiding pattern may be formed over at least part of the layer 305 before the layer 307 is formed. The guiding pattern may include a surface treatment. For instance, polymers may be grated to the layer 305, e.g., by using end groups. Examples of the end groups include polyethylene, polystyrene, poly(methyl methacrylate), polyvinylchloride, polytetrafluorethylene, polydimethylsiloxane, some polyesters, some polyurethanes, acrylics, epoxies, P(t-Butyl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. Polymers may be grafted selectively to the top surfaces of the conductive structures 315 or the top surfaces of insulative structures 317. The surface treatment may change the chemical affinity of polymer A or polymer B with the conductive structures 315 or the insulative structures 317.

In some embodiments, polymer A and polymer B have different mechanical properties. For example, polymer A are more rigid than polymer B. Accordingly, the lamellar structures 335 are more rigid than the lamellar structures 337. In an embodiment, the lamellar structures 335 has a rigidity above a first threshold and the lamellar structures 337 has a rigidity below a second threshold that is lower than the first threshold. As polymer B is more flexible, the block of polymer B may be more easily stretched or compressed between the blocks of polymer A when the diblock copolymer forms the lamellar structures 335 and 337. In an embodiment, a block of polymer B folds onto itself during the self-assembly of the diblock copolymer molecule. The higher rigidity of the lamellar structures 335 help ensure a uniform size of the lamellar structures 337 and consequently, help ensure a single pitch of the DSA pattern. Also, as the lamellar structures 337 is relatively flexible, the lamellar structures 337 can be removed through an etching process that does not or barely etch the lamellar structures 335.

In FIG. 3C, the lamellar structures 337 are removed and forms openings 339A-339C (collectively referred to as “openings 339” or “openings 339”). FIG. 3C shows a cross-sectional view in the X-Y plane. In some embodiments, the lamellar structures 337 may be removed through etching. The lamellar structures 335 and 333, which is more rigid than the lamellar structures 337 may be barely etched or not etched at all. But given the multi-pitch pattern in the layer 305, the removal of the lamellar structures 337 is not sufficient. The lamellar structures 335C and 333 need to be removed too since they do not match the pitch pattern of the region 320 and cannot be used for patterning over the region 320.

In FIG. 3D, the lamellar structures 335C and 333, which includes the more rigid polymer in the diblock copolymer, are removed. The lamellar structures 335A and 335B need to be reserved for patterning over the region 310. The removal of the lamellar structures 335C and 333 is done by using a cut mask 340. The cut mask 340 is over the region 310. An edge of the cut mask 340 is aligned (e.g., overlaps), along the Y axis, with an edge 345 of the region 310 where the region 310 contacts with the region 320. The cut mask 340 may over the lamellar structures 335A and 335B and prevents the lamellar structures 335A and 335B from being removed in the process of removing the lamellar structures 335C and 333. The cut mask 340 is necessary as the lamellar structures 335 and 333 all include the same polymer in the diblock copolymer. Without the cut mask 340, the lamellar structures 335A and 335B would be removed together with the lamellar structures 335C and 333.

In FIG. 3E, dielectric structures 355A and 355B are formed. The dielectric structures 355A and 355B may each include a dielectric material, such as silicon oxide (SiO), silicon nitride (SiN), silicon carbide (SiC), silicon oxynitride (SiOₓN_{y}, where x and y are integers), and so on. The dielectric structures 355A and 355B may be referred as hard masks, which can used for forming additional metal lines or vias. The dielectric structure 355A is between the lamellar structures 335A and 335B and is over one of the conductive structures 315 in the region 310. The dielectric structure 355B is over the other one of the conductive structures 315 in the region 310 and over the region 320. The dielectric structure 355B is formed cross the edge 345 of the activation region 310. To pattern the activation region, a portion of the dielectric structure 355B (e.g., the portion over the other one of the conductive structures 315) needs to be removed. Therefore, the process in FIGS. 3A-3E requires additional lithography steps to use the cut mask 340 to remove the single pitch DSA pattern generated over the region 320 and to generate the multi-pitch pattern that cannot be generated by DSA.

FIGS. 4A-4E illustrate multi-pitch patterning through a cross-linkable block copolymer, according to some embodiments of the disclosure. FIG. 4A shows a layer 405. The layer 405 includes a region 410 and a region 420. The region 410 may be an embodiment of the active region 210 or 230 in FIG. 2. The region 420 may be an embodiment of the transition region 220 in FIG. 2. In other embodiments, the layer 405 may include more or different regions. For instance, the layer 405 may include another active region arranged at the opposite side of the region 420 from the region 410. The layer 405 may be the same or similar as the layer 305 in FIG. 3A.

The region 410 include conductive structures 415 (individually referred to as “conductive structure 415”) and insulative structures 417 (individually referred to as “insulative structure 417”). The conductive structures 415 alternative with the insulative structures 417. The conductive structures 415 have longitudinal axes along the Y axis. Two adjacent conductive structures 415 are separated and insulated by an insulative structure 417. The conductive structures 415 may include one or more metals, such as Co, Al, Cu, Al-doped Cu, Ru, Mo, Ti, W, and so on. The insulative structures 417 may include one or more electrical insulators. An electrical insulator may be a dielectric material, hysteretic material, and so on. The dielectric material may be low-k dielectric, high-k dielectric, and so on. Examples of the dielectric material include silicon oxides, doped silicon oxides, fluorinated silicon oxides, carbon doped oxides, metal oxide (e.g., alumina, etc.), carbon nitride, carbide, and so on. The hysteretic material may be ferroelectric materials, antiferroelectric materials, and so on.

The region 420 include a conductive structure 425 and insulative structures 427 (individually referred to as “insulative structure 427”). The conductive structure 425 is separated from a conductive structure 415 (i.e., the conductive structure 415 that is closest to the conductive structure 425) by an insulative structure 427 (i.e., the insulative structure 427 between the conductive structure 415 and the conductive structure 425). Even though FIG. 4A shows one conductive structure 425 in the transition region, the region 420 may include multiple conductive structures 425, which may be separated by insulative structures 427 that alternate with the conductive structures 425. The region 420 has a larger pitch than the region 410.

A layer 407 is formed over the layer 405. The layer 407 includes a cross-linkable diblock copolymer. The diblock copolymer may include two polymers: polymer A and polymer B. A molecule of the diblock copolymer (e.g., a diblock copolymer molecule 402) may include a block of polymer A (e.g., a polymer A block 404) and a block of polymer B (e.g., a polymer B block 406). A chain of the diblock copolymer has a repetitive pattern of blocks of polymer A alternating with blocks of polymer B. The polymer A block 404 may include predominantly a chain of covalently linked monomer A (e.g., A-A-A-A-A . . . ), whereas the polymer B block 406 may include predominantly a chain of covalently linked monomer B (e.g., B-B-B-B-B . . . ). The monomers A and B may represent any of the different types of monomers used in block copolymers known in the arts. Examples of the polymer A and polymer B include polyethylene, polystyrene, polyvinylchloride, polytetrafluorethylene, polydimethylsiloxane, some polyesters, some polyurethanes, acrylics, epoxies, P(t-Butyl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. In other embodiments, the polymer A or polymer B may be other polymers.

In some embodiments, the block of polymer A and the block of polymer B have different chemical properties. As one example, one of the blocks may be relatively more hydrophobic (e.g., water disliking) and the other may be relatively more hydrophilic (water liking). As another example, one of the blocks may be relatively more similar to oil and the other block may be relatively more similar to water. Such differences in chemical properties between the different blocks of polymers, whether a hydrophilic-hydrophobic difference or otherwise, may cause the diblock copolymer molecule to self-assemble. For example, the self-assembly may be based on microphase separation of the polymer blocks. Conceptually, this may be similar to the phase separation of oil and water which are generally immiscible. Similarly, differences in hydrophilicity between the polymer blocks (e.g., one block is relatively hydrophobic and the other block is relatively hydrophilic), may cause a roughly analogous microphase separation where the different polymer blocks try to separate from each other due to chemical dislike for the other.

However, because the polymer blocks are covalently bonded to one another, they cannot be completely separated on a macroscopic scale. Rather, polymer blocks of a given type may tend to segregate or conglomerate with polymer blocks of the same type of other molecules. Self-assembly of the diblock copolymer, whether based on hydrophobic-hydrophilic differences or otherwise, may be used to form extremely small periodic structures (e.g., precisely spaced nanoscale structures). In some embodiments, the diblock copolymer can be used to form lamellar structures based on which patterning of metal lines, vias, or other components of IC devices may be performed. The dimensions of the lamellar structures are dependent upon the molecular weight, the lengths of the polymer blocks, and so on.

In the embodiments of FIG. 4A, the diblock copolymer is cross-linkable through functions groups. As shown in FIG. 4A, each of the polymer A block 404 and the polymer B block 406 includes functional groups that make the diblock copolymer cross-linkable. Examples of the functional groups include epoxide group, azide group, vinyl group, cinnamoyl group, propargyl group, and so on. For purpose of illustrations, each of the polymer A block 404 and the polymer B block 406 includes three functional groups in FIG. 4A. In other embodiments, the polymer A block 404 or the polymer B block 406 may include a different number of function groups. Also, the polymer A block 404 may include different functional groups from the polymer B block 406. Further, the polymer A block 404 or the polymer B block 406 does not include any functional group in some embodiments.

In some embodiments, the diblock copolymer is photo cross-linkable, meaning one or more chains of the diblock copolymer can be cross-linked after the diblock copolymer is exposed to light radiation, such as ultraviolet (UV) light radiation. For instance, the one or more chains may be linked through a bond or a sequence of bonds as the diblock copolymer is exposed to light radiation. The cross-links may be between the functional groups in the diblock copolymer. The diblock copolymer may be in an amorphous phase before the cross-linking. After the cross-linking, the amorphous phase may be reserved, which can prevent self-assembly of the diblock copolymer.

In FIG. 4B, the portion of the layer 407 that is over the region 420 is exposed to light. The light radiation converts the portion of the layer 407 into a structure 432. The structure 432 includes an amorphous phase of the diblock copolymer, which is produced through cross-linking of the functional groups in the diblock copolymer. The other portion of the layer 407 that is over the region 410 is not exposed to light and therefore, is not cross-linked. The uncross-linked portion of the layer 407 constitutes a structure 434 over the region 410. The structures 432 and 434 constitute a new layer 430.

As shown in FIG. 4B, a light blocker 436 is applied to block light from the structure 434. In some embodiments, the light blocker 436 may be applied to the light source that emits light onto the diblock copolymer. In other embodiments, the light blocker 436 may be applied to the structure 434. The orientation (e.g., position, direction, or both) of the light blocker 436 can be controller so that one or more edges of the structure 432 are aligned with corresponding edges of the region 420. For instance, the edges of the structure 432 in parallel with the Y-Z plane (i.e., perpendicular to the X axis) are aligned with the edges of the region 420 in parallel with the Y-Z plane (i.e., perpendicular to the X axis). Accordingly, the borderline between the structures 432 and 434 is aligned with the borderline between the region 420 and the region 410.

In FIG. 4C, DSA of the diblock copolymer occurs in the structure 434 and forms lamellar structures 435A and 435B (collectively referred to as “lamellar structures 435” or “lamellar structure 435”) and lamellar structures 437A and 437B 337C (collectively referred to as “lamellar structures 437” or “lamellar structure 437”). In some embodiments, the lamellar structures 435 include one of the polymers in the diblock copolymer, and the lamellar structures 437 includes the other polymer in the diblock copolymer. For instance, a lamellar structure 435 may include the polymer A block 404. A lamellar structure 437 may include the polymer B block 406. The lamellar structures 435 and 437 may include crystalline polymers. For instance, each lamellar structure 435 includes crystalline phase of polymer A, and each lamellar structure 437 includes crystalline phase of polymer B.

Individual lamellar structures 435 alternative with individual lamellar structures 437, which constitutes a single pitch DSA pattern. The pitch of the DSA pattern is a center-to-center distance between two adjacent lamellar structures 435 or two adjacent lamellar structures 437. The pitch of the DSA pattern may be the same or similar as the metal pitch of the region 410 but is different from the metal pitch of the region 420. The DSA of the diblock copolymer results in alignment of the lamellar structures 435 with the insulative structures 417 and alignment of the lamellar structures 437 with the conductive structures 415. For instance, the edges of a lamellar structure 435, which is over a insulative structure 417, in the Y-Z plane are aligned with the edges of the insulative structure 417 in the Y-Z plane along the Y axis. The edges of a lamellar structure 437, which is over a conductive structure 415, in the Y-Z plane are aligned with the edges of the conductive structure 415 in the Y-Z plane along the Y axis.

The formation of the lamellar structures 435 and 437 may be facilitated by the alternating pattern of the conductive structures 415 and insulative structures 417. In some embodiments, the alternating pattern of the conductive structures 415 and insulative structures 417 may constitute a guiding pattern for the DSA of the diblock copolymer. For instance, polymer A in the diblock copolymer may have stronger chemical affinity with the material in the conductive structures 415 than the material in the insulative structures 417. Additionally or alternatively, polymer B in the diblock copolymer may have stronger chemical affinity with the material in the conductive structures 415 than the material in the insulative structures 417. As a result, the lamellar structures 435, which includes polymer A, are formed over the insulative structures 417, and the lamellar structures 435, which includes polymer B, are formed over the conductive structures 415.

In other embodiments, a guiding pattern may be formed over at least part of the layer 405 before the layer 407 is formed. The guiding pattern may include a surface treatment. For instance, polymers may be grated to the layer 405, e.g., by using end groups. Examples of the end groups include polyethylene, polystyrene, polyvinylchloride, polytetrafluorethylene, polydimethylsiloxane, some polyesters, some polyurethanes, acrylics, epoxies, P(t-Butyl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. Polymers may be grafted selectively to the top surfaces of the conductive structures 415 or the top surfaces of insulative structures 417. The surface treatment may change the chemical affinity of polymer A or polymer B with the conductive structures 415 or the insulative structures 417.

In some embodiments, polymer A and polymer B have different mechanical properties. For example, polymer A are more rigid than polymer B. Accordingly, the lamellar structures 435 are more rigid than the lamellar structures 437. In an embodiment, the lamellar structures 435 has a rigidity above a first threshold and the lamellar structures 437 has a rigidity below a second threshold that is lower than the first threshold. As polymer B is more flexible, the block of polymer B may be more easily stretched or compressed between the blocks of polymer A when the diblock copolymer forms the lamellar structures 435 and 437. In an embodiment, a block of polymer B folds onto itself during the self-assembly of the diblock copolymer molecule. The higher rigidity of the lamellar structures 435 helps ensure a uniform size of the lamellar structures 437 and consequently, help ensure a single pitch of the DSA pattern. Also, as the lamellar structures 437 is relatively flexible, the lamellar structures 437 can be removed through an etching process that does not or barely etch the lamellar structures 435.

The structure 432 remains the same in FIG. 4C. The structure 432 still includes an amorphous phase of the diblock copolymer. As the amorphous state of the diblock copolymer is “frozen” through the photo cross-linking in FIG. 4B before the DSA of the diblock copolymer in FIG. 4C, the photo cross-linking can prevent random fingerprint pattern or horizontal morphology formed over the region 420. Also, the edges of the structure 432 in the Y-Z plane are still aligned with the edges of the region 420 in the Y-Z plane. Accordingly, the single pitch DSA pattern is over the region 410 and is not formed over any portion of the region 420. Thus, the formation of the structure 432 before the DSA of the diblock copolymer can avoid the lithography step of using a cut mask to remove DSA pattern formed on undesired area, e.g., the region 420.

In FIG. 4D, the lamellar structures 437 are removed, e.g., through selective etching. In the selective etching process, a rate of etching the lamellar structures 437 may be higher than a rate of etching the structure 432, which is further higher than a rate of etching the lamellar structures 435. The differentiated etching rate may be because polymer A, which is in the lamellar structures 435, is more rigid than polymer B, which is in the lamellar structures 437, and the structure 432 includes a combination of polymer A and polymer B since the structurer 432 includes the diblock copolymer. As shown in FIG. 4D, the lamellar structures 437 are removed, which forms openings 439A and 439B, the structurer 432 is partially etched, which forms a structure 434, and the lamellar structures 435 are barely etched or not etched at all. The structure 434 is a portion of the structure 432 and also includes the amorphous phase of the diblock copolymer.

In FIG. 4E, dielectric structures 455A and 455B are formed in the openings 439A and 439B, respectively. In some embodiments, the dielectric structures 455A and 455B may be formed by depositing a dielectric material into the openings 439A and 439B. Extra dielectric material may be deposited over the top surfaces of the lamellar structures 435 and the structure 434. The extra dielectric material may be removed after the deposition, e.g., through polishing. The polishing process may remove some portions of the lamellar structures 435 or the structure 434. Examples of the dielectric material include SiO, SiN, SiC, SiOₓN_{y} (where x and y are integers), and so on. The dielectric structures 455A and 455B may be referred as hard masks, which can used for forming additional metal lines or vias.

As shown in FIG. 4E, the dielectric structure 455A is between the lamellar structures 435A and 435B and is over one of the conductive structures 415 in the region 410. The dielectric structure 435B is over the other one of the conductive structures 415 in the region 410 and over the region 420. No dielectric structure is formed over the region 420 due to the presence of the structure 434, which is aligned with the region 420. Thus, compared with the process in FIGS. 3A-3E, the process in FIGS. 4A-4E not only does not require the usage of cut mask but also does not require additional lithography steps to remove undesired hard masks over the region 420 before patterning the area over the region 420. Thus, the process in FIGS. 4A-4E is more efficient.

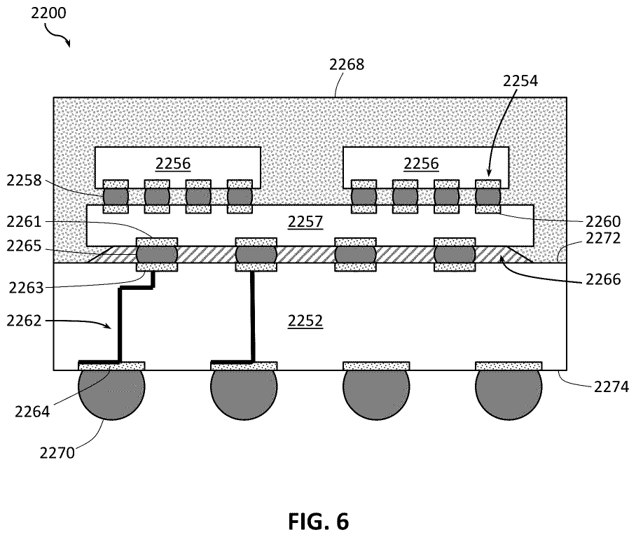

FIGS. 5A-5B are top views of a wafer 2000 and dies 2002 that may include one or more multi-pitch patterns fabricated through one or more cross-linkable copolymers, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 6. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including one or more multi-pitch patterns fabricated through one or more cross-linkable copolymers as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include one or more multi-pitch patterns fabricated through one or more cross-linkable copolymers as disclosed herein may take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 6 is a side, cross-sectional view of an example IC package 2200 that may include one or more IC devices having one or more multi-pitch patterns fabricated through one or more cross-linkable copolymers, according to some embodiments of the disclosure. In some embodiments, the IC package 2200 may be a system-in-package (SiP).

As shown in FIG. 6, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 6 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 6 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 6 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 7.

The dies 2256 may take the form of any of the embodiments of the die 2002 discussed herein and may include any of the embodiments of an IC device having one or more multi-pitch patterns fabricated through one or more cross-linkable copolymers. In embodiments in which the IC package 2200 includes multiple dies 2256, the IC package 2200 may be referred to as a multi-chip package. Importantly, even in such embodiments of an MCP implementation of the IC package 2200, one or more multi-pitch patterns fabricated through one or more cross-linkable copolymers may be provided in a single chip, in accordance with any of the embodiments described herein. The dies 2256 may include circuitry to perform any desired functionality. For example, one or more of the dies 2256 may be ESD protection dies, including one or more multi-pitch patterns fabricated through one or more cross-linkable copolymers as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more multi-pitch patterns fabricated through one or more cross-linkable copolymers, e.g., metal lines as discussed above; in some embodiments, at least some of the dies 2256 may not include any III-N diodes with n-doped wells and capping layers.

The IC package 2200 illustrated in FIG. 6 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 6, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 7 is a cross-sectional side view of an IC device assembly 2300 that may include components having one or more IC devices implementing one or more multi-pitch patterns fabricated through one or more cross-linkable copolymers, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more multi-pitch patterns fabricated through one or more cross-linkable copolymers in accordance with any of the embodiments disclosed herein; e.g., any of the IC packages discussed below with reference to the IC device assembly 2300 may take the form of any of the embodiments of the IC package 2200 discussed above with reference to FIG. 6 (e.g., may include one or more multi-pitch patterns fabricated through one or more cross-linkable copolymers in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 7 includes a package-on-interposer structure 2236 coupled to the first face 2340 of the circuit board 2302 by coupling components 2316. The coupling components 2316 may electrically and mechanically couple the package-on-interposer structure 2236 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2236 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 5B), an IC device (e.g., the IC device of FIGS. 1-2), or any other suitable component. In particular, the IC package 2320 may include one or more multi-pitch patterns fabricated through one or more cross-linkable copolymers as described herein. Although a single IC package 2320 is shown in FIG. 7, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 7, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more multi-pitch patterns fabricated through one or more cross-linkable copolymers as described herein may also be implemented in/on the interposer 2304. The package-on-interposer structure 2236 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 7 includes a package-on-package structure 2234 coupled to the second face 2342 of the circuit board 2302 by coupling components 2328. The package-on-package structure 2234 may include an IC package 2326 and an IC package 2332 coupled together by coupling components 2

such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2234 may be configured in accordance with any of the package-on-package structures known in the art.

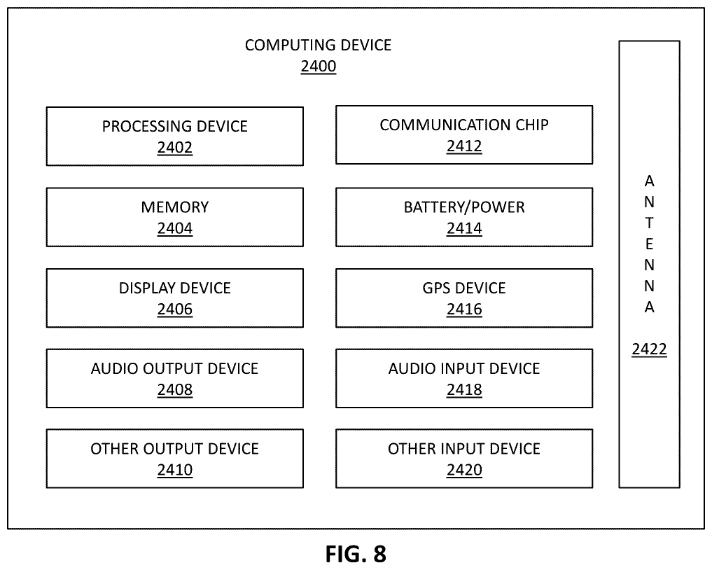

FIG. 8 is a block diagram of an example computing device 2400 that may include one or more components with one or more IC devices having one or more multi-pitch patterns fabricated through one or more cross-linkable copolymers, according to some embodiments of the disclosure. For example, any suitable ones of the components of the computing device 2400 may include a die (e.g., the die 2002 of FIG. 5B) including one or more multi-pitch patterns fabricated through one or more cross-linkable copolymers, according to some embodiments of the disclosure. Any of the components of the computing device 2400 may include an IC device (e.g., the IC devices in FIGS. 1A and 1B) and/or an IC package (e.g., the IC package 2200 of FIG. 6). Any of the components of the computing device 2400 may include an IC device assembly (e.g., the IC device assembly 2300 of FIG. 7).

A number of components are illustrated in FIG. 8 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 8, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408 but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first layer, including a first conductive structure, a second conductive structure in parallel with the first conductive structure in a first direction, an electrical insulator between the first conductive structure and the second conductive structure in a second direction that is perpendicular to the first direction, where a dimension of the first conductive structure in the second direction is smaller than a dimension of the second conductive structure in the second direction; and a second layer including a first structure, an edge of the first structure aligned with an edge of the first conductive structure in the first direction, and a second structure including an amorphous polymer.

Example 2 provides the IC device according to example 1, where the first structure includes a crystalline polymer, the crystalline polymer includes a first monomer, the amorphous polymer includes the first monomer and a second monomer, and the second monomer is different from the first monomer.

Example 3 provides the IC device according to example 1 or 2, further including a first transistor comprising a first channel region coupled to the first conductive structure; and a second transistor comprising a second channel region coupled to the second conductive structure.

Example 4 provides the IC device according to any of the preceding examples, where the first structure includes a dielectric material.

Example 5 provides the IC device according to any of the preceding examples, where another edge of the first structure is aligned with an edge of the electrical insulator in the first direction, and an edge of the second structure is aligned with the edge of the electrical insulator in the first direction.

Example 6 provides an IC device, including a plurality of first conductive structures; a plurality of second conductive structures in parallel with the first conductive structure in a first direction; a plurality of insulative structures between individual first conductive structure and individual second conductive structures; a plurality of first structures, an individual first structure over an individual first conductive structure, an edge of the individual first structure aligned with an edge of the individual first conductive structure; a second structure over the plurality of second conductive structures, the second structure including an amorphous polymer, a first transistor comprising a first channel region coupled to at least one of the plurality of first conductive structures; and a second transistor comprising a second channel region coupled to at least one of the plurality of second conductive structures, where a distance between centers of two adjacent first conductive structures is smaller than a distance between centers of two adjacent second conductive structures.

Example 7 provides the IC device according to example 6, where the edge of the individual first structure is aligned with the edge of the individual first conductive structure in a first direction, the distance between the centers of the two adjacent first conductive structures is along a second direction, and the first direction is perpendicular to the second direction.

Example 8 provides the IC device according to example 6 or 7, where an edge of the second structure is aligned with an edge of an individual insulative structure, the individual insulative structure is between a first conductive structure and a second conductive structure.

Example 9 provides the IC device according to any one of examples 6-8, where the individual first structure includes a crystalline polymer, the crystalline polymer includes a first monomer, the amorphous polymer includes the first monomer and a second monomer, and the second monomer is different from the first monomer

Example 10 provides the IC device according to any one of examples 6-9, where the individual first structure includes a dielectric material.

Example 11 provides a method for forming an IC device, including forming a first layer over a second layer, the first layer including a copolymer, the second layer including a first conductive structure, a second conductive structure, and an insulative structure between the first conductive structure and the second conductive structure; forming a structure from a first section of the first layer, the first structure including an amorphous phase of the copolymer; and forming a lamellar pattern from a second section of the first layer through DSA of the copolymer, the lamellar pattern including a first lamellar structure and a second lamella structure, where an edge of the structure is aligned with an edge of the insulative structure in a first direction, a dimension of the first conductive structure in a second direction is smaller than a dimension of the second conductive structure in the second direction, and the first direction is perpendicular to the second direction.

Example 12 provides the method according to example 11, where the structure is formed before the lamellar pattern is formed.

Example 13 provides the method according to example 11 or 12, where forming the structure from the first section of the first layer includes exposing the first section of the first layer to light, where chemical bonds in the copolymer in the first section are cross-linked under the light.

Example 14 provides the method according to example 13, where forming the structure from the first section of the first layer further includes blocking the first section of the first layer from the light.

Example 15 provides the method according to any one of examples 11-14, where the second layer further including an additional insulative structure, the first conductive structure is between the additional insulative structure and the insulative structure in the second direction, the first lamellar structure is over the additional insulative structure, and the second lamellar structure is over the first conductive structure.

Example 16 provides the method according to any one of examples 11-15, where the copolymer includes a first monomer and a second monomer, the first lamellar structure or the second lamellar structure includes a crystalline polymer, the crystalline polymer includes one of the first monomer and the second monomer.

Example 17 provides the method according to example 16, where the structure includes the first monomer and the second monomer.

Example 18 provides the method according to any one of examples 11-17, where an edge of the first lamellar structure or the second lamellar structure is aligned with the edge of the insulative structure in the first direction.

Example 19 provides the method according to example 18, where another edge of the first lamellar structure or the second lamellar structure is aligned with an edge of the first conductive structure in the first direction.

Example 20 provides the method according to any one of examples 11-19, further including forming an opening in the lamellar pattern by removing the first lamellar structure or the second lamellar structure; and providing a dielectric material into the opening, the dielectric material having a hardness greater than a hardness of the copolymer.

Example 21 provides an IC package, including the IC device according to any one of examples 1-10; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-10 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-10 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 11-20, further including processes for forming the IC device according to any one of claims 1-10.

Example 35 provides the method according to any one of examples 11-20, further including processes for forming the IC package according to any one of the claims 21-23.

Example 36 provides the method according to any one of examples 11-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first layer, comprising:
a first conductive structure,
a second conductive structure in parallel with the first conductive structure in a first direction, and
an electrical insulator between the first conductive structure and the second conductive structure in a second direction that is perpendicular to the first direction,
wherein a dimension of the first conductive structure in the second direction is smaller than a dimension of the second conductive structure in the second direction; and
a second layer, comprising:
a first structure, an edge of the first structure aligned with an edge of the first conductive structure in the first direction, and
a second structure comprising an amorphous polymer.

2. The IC device according to claim 1, wherein:
the first structure comprises a crystalline polymer,
the crystalline polymer comprises a first monomer,
the amorphous polymer comprises the first monomer and a second monomer, and
the second monomer is different from the first monomer.

3. The IC device according to claim 1, further comprising:
a first transistor comprising a first channel region coupled to the first conductive structure; and
a second transistor comprising a second channel region coupled to the second conductive structure.

4. The IC device according to claim 1, wherein the first structure comprises a dielectric material.

5. The IC device according to claim 1, wherein:
another edge of the first structure is aligned with an edge of the electrical insulator in the first direction, and
an edge of the second structure is aligned with the edge of the electrical insulator in the first direction.

6. An integrated circuit (IC) device, comprising:
a plurality of first conductive structures;
a plurality of second conductive structures in parallel with the plurality of first conductive structures in a first direction;
a plurality of insulative structures between individual first conductive structures and individual second conductive structures;
a plurality of first structures, an individual first structure over an individual first conductive structure, an edge of the individual first structure aligned with an edge of the individual first conductive structure in the first direction;
a second structure over the plurality of second conductive structures, the second structure comprising an amorphous polymer;
a first transistor comprising a first channel region coupled to at least one of the plurality of first conductive structures; and
a second transistor comprising a second channel region coupled to at least one of the plurality of second conductive structures,
wherein a distance between centers of two adjacent first conductive structures in a second direction is smaller than a distance between centers of two adjacent second conductive structures in the second direction, and the second direction is perpendicular to the first direction.

7. The IC device according to claim 6, wherein an edge of the second structure is aligned with an edge of an individual insulative structure, the individual insulative structure is between a first conductive structure and a second conductive structure.

8. The IC device according to claim 6, wherein the individual first structure comprises a crystalline polymer.

9. The IC device according to claim 8, wherein:
the crystalline polymer comprises a first monomer,
the amorphous polymer comprises the first monomer and a second monomer, and
the second monomer is different from the first monomer

10. The IC device according to claim 6, wherein the individual first structure comprises a dielectric material.

11. A method for forming an integrated circuit (IC) device, comprising:
forming a first layer over a second layer, the first layer comprising a copolymer, the second layer comprising a first conductive structure, a second conductive structure, and an insulative structure between the first conductive structure and the second conductive structure;
forming a structure from a first section of the first layer, the first structure comprising an amorphous phase of the copolymer; and
forming a lamellar pattern from a second section of the first layer through directed self-assembly of the copolymer, the lamellar pattern comprising a first lamellar structure and a second lamella structure,
wherein an edge of the structure is aligned with an edge of the insulative structure in a first direction, a dimension of the first conductive structure in a second direction is smaller than a dimension of the second conductive structure in the second direction, and the first direction is perpendicular to the second direction.

12. The method according to claim 11, wherein the structure is formed before the lamellar pattern is formed.

13. The method according to claim 11, wherein forming the structure from the first section of the first layer comprises:
exposing the first section of the first layer to light, wherein chemical bonds in the copolymer in the first section are cross-linked under the light.

14. The method according to claim 13, wherein forming the structure from the first section of the first layer further comprises:
blocking the first section of the first layer from the light.

15. The method according to claim 11, wherein:
the second layer further comprising an additional insulative structure,
the first conductive structure is between the additional insulative structure and the insulative structure in the second direction,
the first lamellar structure is over the additional insulative structure, and
the second lamellar structure is over the first conductive structure.

16. The method according to claim 11, wherein:
the copolymer comprises a first monomer and a second monomer,
the first lamellar structure or the second lamellar structure comprises a crystalline polymer,
the crystalline polymer comprises one of the first monomer and the second monomer.

17. The method according to claim 16, wherein:
the structure comprises the first monomer and the second monomer.

18. The method according to claim 11, wherein:
an edge of the first lamellar structure or the second lamellar structure is aligned with the edge of the insulative structure in the first direction.

19. The method according to claim 18, wherein:
another edge of the first lamellar structure or the second lamellar structure is aligned with an edge of the first conductive structure in the first direction.

20. The method according to claim 11, further comprising:
forming an opening in the lamellar pattern by removing the first lamellar structure or the second lamellar structure; and
providing a dielectric material into the opening, the dielectric material having a hardness greater than a hardness of the copolymer.
